(19) United States
(12) Patent Application Publication
(10) Pub. No.: US 2014/0099796 A1
(43) Pub. Date: Apr. 10, 2014

(54) METHOD FOR DEVELOPING LOW DIELECTRIC CONSTANT FILM AND DEVICES OBTAINED THEREOF

(71) Applicants: Centro de Investigación y de Estudios Avanzados del Instituto Politécnico Nacional, Col. San Pedro Zacatenco (MX); IMEC, Leuven (BE)

(72) Inventors: Patrick Verdonck, Zaventem (BE); Srinivas Godavarthi, Leuven (BE); Yasuhiro Matsumoto, Leuven (BE)

(73) Assignees: Centro de Investigación y de Estudios Avanzados del Instituto Politécnico Nacional, Col. San Pedro Zacatenco (MX); IMEC, Leuven (BE)

(21) Appl. No.: 14/045,678

(22) Filed: Oct. 3, 2013

Related U.S. Application Data
(60) Provisional application No. 61/709,879, filed on Oct. 4, 2012.

(51) Int. Cl. H01L 21/02

(52) U.S. Cl. CPC H01L 21/02126
USPC 438/786

(57) ABSTRACT

A method for porogen removal of porous SiOCH film is provided, as well as devices obtained thereof. The devices and associated methods are in the field of advanced semiconductor interconnect technology, and more in particular in the development of dielectric films with low-k value.

### INCORPORATION BY REFERENCE TO RELATED APPLICATIONS

Any and all priority claims identified in the Application Data Sheet, or any correction thereto, are hereby incorporated by reference under 37 CFR 1.57. This application claims the benefit of U.S. Provisional Application No. 61/709,879 filed on Oct. 4, 2012. Each of the aforementioned applications is incorporated by reference herein in its entirety, and each is hereby expressly made a part of this specification.

### FIELD OF THE INVENTION

A method for porogen removal of porous SiOCH film is provided, as well as devices obtained thereof. The devices and associated methods are in the field of advanced semiconductor interconnect technology, and more in particular in the development of dielectric films with low-k value.

### BACKGROUND OF THE INVENTION

One of the targets of microelectronic industry is to reduce the dielectric constant of the intermetal dielectric (IMD), thereby decreasing the RC delay and power consumption, while enhancing the signal to noise ratio and other electrical parameters. Porous hydrogenated silicon oxycarbide (SiOCH) has attracted ultra low-k researchers' interest thanks to its properties. For example, these films are chemically resistant during process integration while maintaining their low dielectric constant. Porous SiOCH films are obtained through either a structural or a subtractive way. The subtractive method requires at least two process steps: 1) co-deposition of a SiOCH precursor and a sacrificial porogen hydrocarbon, such as a CHₓ based/hydrocarbon, precursor, and 2) removal of porogen. This removal can be done by several techniques, of which a remote plasma treatment and a UV cure are the most common. The UV cure treatment also may raise skeleton cross linking and enhance film mechanical properties and may be, therefore, used as a third step in the subtractive method, when the second process step is remote plasma. However, the use of plasma treatment and UV cure for the development of dielectric films with low-k value can cause undesirable changes to the surface properties of the film and/or wafer. This can lead to damages of the silica matrix or in the case of UV cure the porogen is not completely removed, thereby leading to higher dielectric constant (k) values, higher leakage current, and other reliability problems.

### Summary of Certain Inventive Aspects

In certain embodiments, a new method is provided for developing a film with a dielectric constant value below 2.3, while minimizing the damage caused to the silica matrix and thereby overcoming deficiencies of the prior art methods.

In a first aspect, a method is provided for developing films with dielectric value below 2.3, the method comprising the steps of: a) depositing a porogen material containing SiOCH film on a wafer, whereby a matrix material forming the skeleton of the film is co-deposited with a cyclic hydrocarbon forming the sacrificial porogen; b) removing the sacrificial porogen with a hot-wire-induced chemical vapor process (HWCVP), and c) UV curing of the film for improving the Young's modulus (E) and hardness (H) properties of the film. This method has the advantage that the porosities obtained are as high as with the techniques mentioned in the prior art, for example remote plasma, while minimizing the damage caused to the film.

In an embodiment according to the first aspect, the removal of sacrificial porogen with HWCVP further comprises the steps of: a) positioning the wafer on the substrate holder of a HWCVD equipment; b) supplying the HWCVD chamber with a gas, preferably a hydrogen (H) based gas; c) heating the filaments at a predetermined temperature and for a predetermined time; d) stopping the flow of the gas once the sacrificial porogen is removed; e) cooling down the sample/wafer and the system in an inert atmosphere, thereby preserving the filament; and f) removing the sample/wafer from the tool.

In an embodiment according to the first aspect, the method may be improved by keeping the temperature of the filament in HWCVD equipment between 1500° C. and 2000° C.

In an embodiment according to the first aspect, the filament in HWCVD equipment is a single coiled type filament, preferably comprising refractory metals, such as Tungsten (W), Ta, Nb, Mb, etc.

In an embodiment according to the first aspect, the filament is positioned at a predetermined distance from the SiOCH, for example, around 5 cm, or 1 cm to 10 cm. This allows for the temperature of the sample/wafer to stay at a significantly lower temperature compared to the filament, for example, around 400° C. The distance between the filament and the film also allows for uniform distribution of Hydrogen (H) atoms on the film. As a result, the sacrificial porogen can be removed from the film at a lower temperature compared to the state-of-the art techniques. The distance selected can be such that the temperature of the sample/wafer is about 400° C. or less.

In an embodiment according to the first aspect, the method involves the step of ex situ monitoring of the SiOCH film porosity and pore size distribution uses Ellipsometric porosimetry.

In an embodiment according to the first aspect, the step of ex situ monitoring involves the recording of Fourier Transform Infrared (FTIR) spectra in absorption mode with a resolution better than 1 cm⁻¹, within the 400 to 4000 cm⁻¹ range, in a nitrogen atmosphere.

In an embodiment according to the first aspect, the step of ex situ monitoring further includes the recording of XRR spectra with an incident angle of 1500 sec for an omega-2 theta range of 200 sec to 10000 sec.

### BRIEF DESCRIPTION OF THE DRAWINGS

For a better understanding of the disclosure, reference will now be made, by way of example only, to the accompanying drawings in which:

FIG. 1 shows the FTIR spectra of the remaining C—CH₃ and C—CH₂ groups in the 2800 cm⁻¹ to 3000 cm⁻¹ range as a function of filament temperature, for a H₂ treatment during 15 minutes.

FIG. 2 shows other interesting parts of the FTIR spectra.

FIGS. 3A-D show SIMS depth profiles for the as deposited film and films after H treatments at 1500° C., 1800° C. and 2000° C., respectively.

FIG. 4 presents the resulting dielectric constant of the films.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Moreover, the term top and the like in the description and the claims are used for descriptive purposes and not necessarily for describing relative positions. It is to be understood that the terms so used are interchangeable under appropriate circumstances and that the preferred embodiments described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary preferred embodiments, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that preferred embodiments may be practiced without these specific details. In other instances, well-known methods, structures and techniques have not been shown in detail in order not to obscure an understanding of this description.

The invention will now be described by a detailed description of several preferred embodiments. It is clear that other preferred embodiments can be configured according to the knowledge of persons skilled in the art without departing from the true spirit or technical teaching of the invention as defined by the appended claims.

Atomic hydrogen generated by hot wire chemical vapor deposition (HWCVD) has been used for etching the residual oxide and to passivate surface defects. This process has some potential advantages towards plasmas, as there is no plasma involved which may cause unintentional changes of film or wafer surface properties. This technique also enjoys the benefit to be able to generate high amounts of hydrogen atoms. Considering these characteristics, a HWCVD based subtractive process is potentially interesting for the porogen removal of porous SiOCH films.

A method is provided for developing films with dielectric value below 2.3, the method comprising the steps of: a) depositing a porogen material containing SiOCH film on a wafer, whereby a matrix material forming the skeleton of the film is co-deposited with a cyclic hydrocarbon forming the sacrificial porogen; b) removing the sacrificial porogen with a Hot-wire-induced chemical vapor process (HWCVP); and c) UV curing of the film for improving the Young's modulus (E) and hardness (H) properties of the film. This method has the advantage that the porosities obtained comparable or better with the ones reported in the prior art, for example remote plasma, while minimizing the damage caused to the film.

The method makes use of the subtractive technique for removing sacrificial porogens from a SiCOH film. The porogen removal from porogenated SiCOH films is achieved using a hot wire chemical vapor deposition (HWCVD) equipment, wherein molecular hydrogen is dissociated into atomic hydrogen by the hot wires thereby removing the hydrocarbon groups from the porogenated SiCOH films. In order to efficiently remove the sacrificial porogen from the porous film, the temperature and duration of the exposure treatment were selected according to the thickness of the film. For example, using FTIR, XRR, SIMS, Ellipsometric Porosimetry and C-V analyses, it was possible to determine that for temperatures higher than 1700° C., efficient porogen removal occurred. For temperatures higher than 1800° C., the presence of OH groups has been observed. The dielectric constant was the lowest, 2.28, for the samples processed at a filament temperature of 1800° C., although porosity measurements showed higher porosity for the films deposited at the higher temperatures. XRR and SIMS analyses indicated densification and W incorporation at the top few nanometers of the films.

The co-deposition of film on 300 mm diameter wafers was achieved by introducing an alkylsilane gas, responsible to produce the SiOCH network, and a cyclic hydrocarbon gas for creating the porogen material. The second process step involves the removal of porogen from the porous film. This can be carried out on individual samples (coupons) or a full wafer (samples) using a HWCVD reactor with a filament comprising refractory materials, such as Tungsten (W). The filament is not in direct contact with the sample/wafer. As a result the temperature of the sample/wafer remains low thereby reducing the risk of damaging the film. Single coiled type filaments can be used for all the treatments. Other details of this system were described elsewhere in the prior art.

The proposed method is exemplified with the removal of sacrificial porogen from a film with thickness of 100 nm and with within wafer non-uniformity of less than 10%. The film deposition conditions can include those conventionally employed to deposit such films. The removal of porogen from the film was carried out on individual samples. For this example, this was achieved using a 200 sccm H₂ flow in a HWCVD reactor with a tungsten (W) filament. The distance between the filament and sample was set at 5 cm. Due to the distance between the filament and the sample/wafer, there is no significant rise of the temperature of the sample/wafer and as a result the risk for damaging the film is minimized. Single coiled type filaments were used for all the treatments.

In this example Fourier Transform Infrared (FTIR) spectra were recorded in absorption mode with a resolution better than 1 cm⁻¹, within the 400 to 4000 cm⁻¹ range, in a nitrogen atmosphere. Ellipsometric porosimetry with ex situ spectroscopic ellipsometry was used for porosity and pore size distribution measurements. XRR spectra were recorded with an incident angle of 1500 sec for an omega-2 theta range of 200 sec to 10000 sec. The fitted results were used to evaluate layer thickness and to indicate density modifications caused by the treatments. SIMS depth profiling was performed with a Cameca IMS-6F ion microprobe. A finely focused cesium ion (Cs+) beam with ion energy of 5 keV and with an angle of incidence of about 45° with respect to the normal, scanned a 300×300 micron crater on the sample surface. The primary ion current was varied from 2 to 20 nA. Secondary CsM+ cluster ions and also Cs2M+ cluster ions (where M=Si, O, C, H and W) emitted from the central part of the bombarded area were analyzed with a double-focusing mass spectrometer and were detected with an Electron Multiplier, or with a Faraday Cup, in accordance with their intensities. The dielectric constant (k) was extracted from C-V curves, measured at 100 kHz, using a metal-insulator-semiconductor structure. In this case platinum dots were used as front contacts and a Ga—In alloy was used as a backside ohmic contact. Only capacitors with a dissipation factor less than 0.1 were used for k-value extraction.

There is an extensive number of reports on HWCVD based atomic hydrogen processes and on the influence of process parameters like filament temperature, substrate temperature, etc. These process parameters were selected for passivating c-Si surfaces or removal of residual oxide. However, in the methods of certain embodiments, the removal of porogens from a SiCOH film is targeted and at the same time minimizes any kind of damage. The process development included selection of filament temperature to remove the porogen while targeting an ultra low-k value. Porogen removal has been generally analyzed with FTIR by observing the peak area of the C—CHₓ bending bond (2800-3000 cm⁻¹).

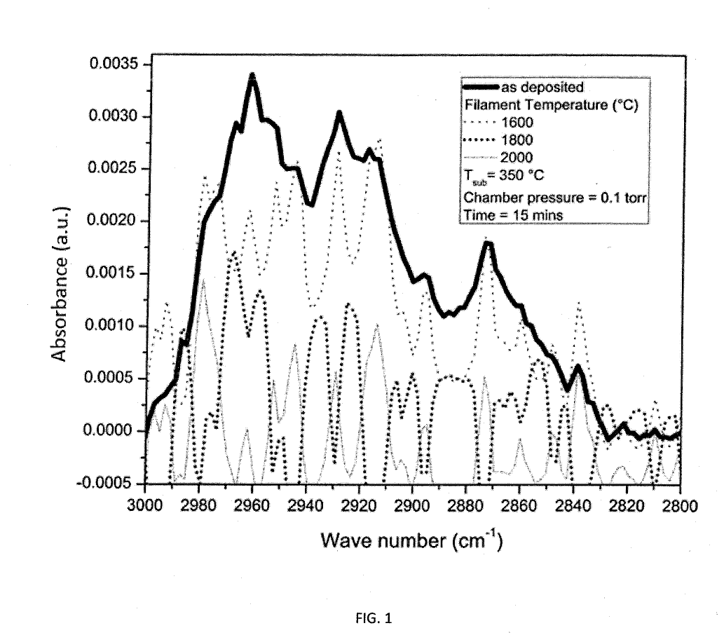

FIG. 1 shows the FTIR spectra of the remaining C—CH₃ and C—CH₂ groups in the 2800 cm⁻¹ to 3000 cm⁻¹ range as a function of filament temperature, for a H₂ treatment during 15 minutes. One may immediately observe that, in the 1500° C. to 1800° C. range, at higher temperatures more porogen has been removed. For temperatures higher than 1800° C., the influence of the filament temperature did not significantly change the C—CHₓ content.

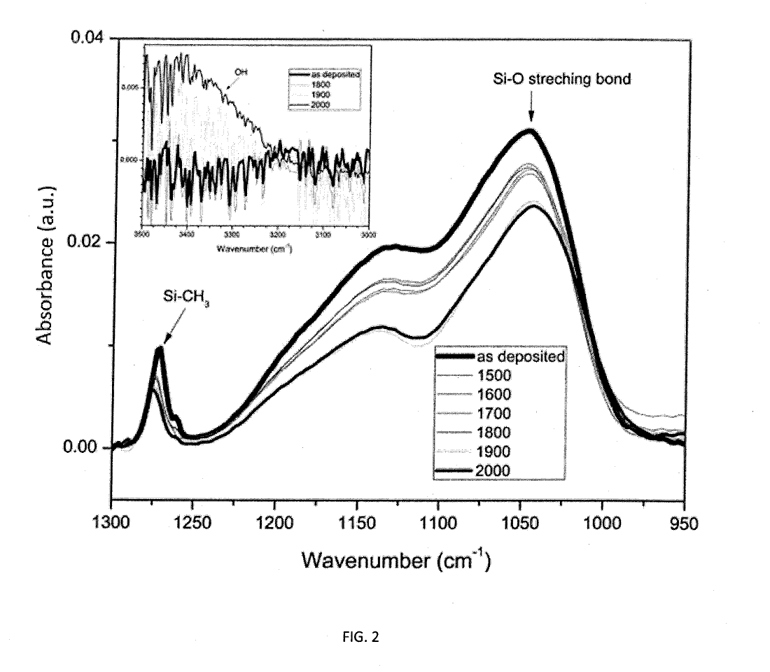

FIG. 2 shows other interesting parts of the FTIR spectra: the broad absorption band in the region of 980-1250 cm⁻¹ which is the result of at least four overlapping bonds, the Si—(CH₃)ₓ region around 1280 cm⁻¹ and the —OH region in the 3000-3500 region. No Si—H peaks (around 2170 cm⁻¹) were observed.

The evolution of the amplitude of the Si—CH₃ peak is similar to the C—CHₓ peaks. The single most interesting feature of the broad absorption band in the region of 980-1250 cm⁻¹ is that the peaks retained their maximum at approximately the same wave number, independent of the filament temperature. This is a strong indication that there was little transition from cage and suboxide types of Si—O bonds to network bonds, which is very different from when the as deposited films were treated by a UV cure, as reported in the prior art. The FTIR spectra in the 3000-3500 cm⁻¹ region indicate that there is some water incorporation in the films when they were treated at temperatures higher than 1800° C.

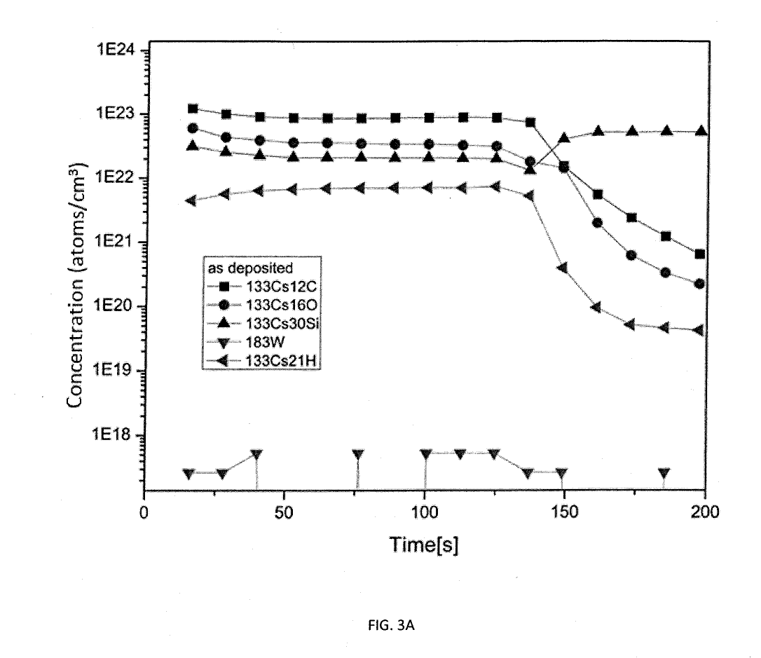

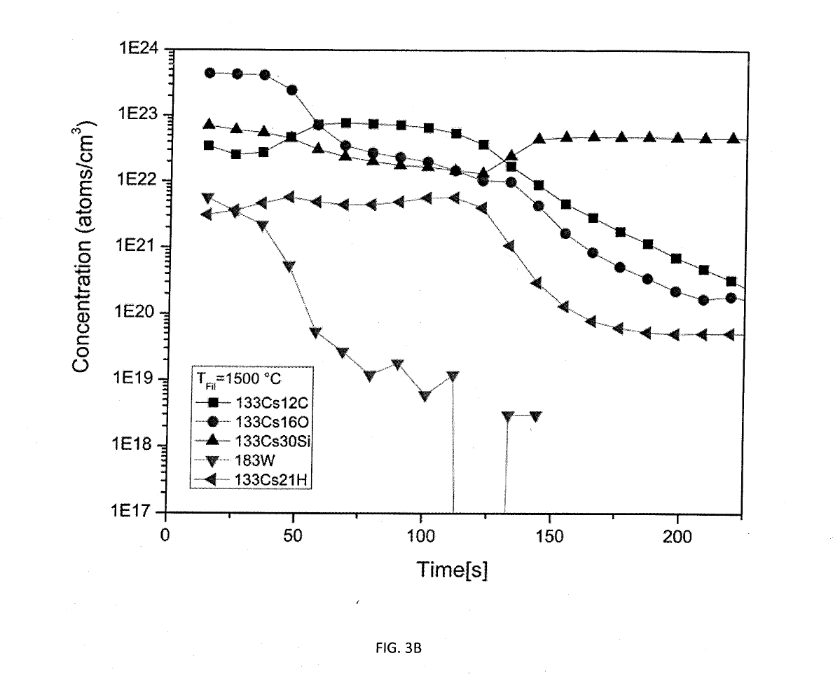

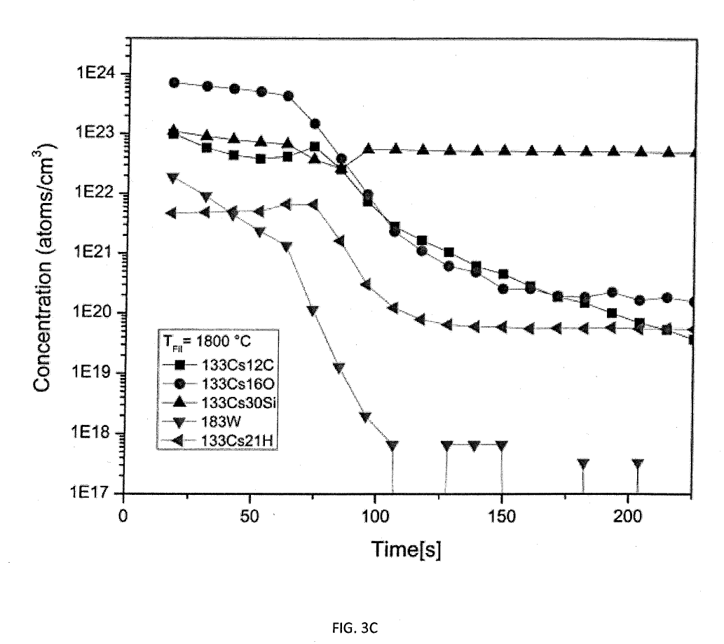

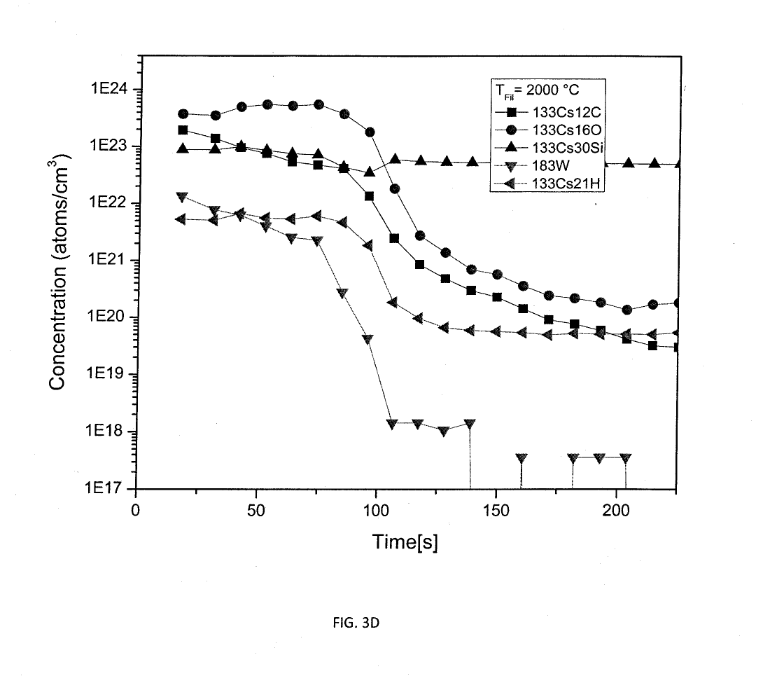

FIG. 3 shows SIMS depth profiles for the as deposited film and films after H treatments at 1500° C., 1800° C. and 2000° C. The very first point of the spectra gives an indication of the situation at the surface of the wafer, which is often quite different from the situation of the bulk of the film. The as-deposited film has a very good depth uniformity of the composition of the film. After the 1500° C. treatment, C and H have been partially removed from the film: the bottom two thirds of the film retained its chemical composition.

Tables I and II show the results of XRR analyses of the resulting films. These tables also show the results of the analysis when a remote plasma was applied to the film. This was the standard remote plasma, as detailed in the prior art. In order to be able to fit the XRR spectra, it was necessary to divide the total film into up to five different layers, all with different densities. On the other hand, there was always one layer much thicker than the others, with a low density (Layer 2). The data in Table II show that the density of this Layer 2 decreased with filament temperature, up to 1900° C., after which it increased again somewhat for the 2000° C. sample.

TABLE I
XRR Thickness (nm)

| | | | | | | | | after |
|---|---|---|---|---|---|---|---|---|
| | As | | | | | | | plasma |
| Layer | grown | 1500° C. | 1600° C. | 1700° C. | 1800° C. | 1900° C. | 2000° C. | (reference) |
| Layer 1 | | | 0.6 | 0.7 | 1.4 | 0.6 | 0.5 | 1.2 |
| Layer 2 | 107 | 93.9 | 93.5 | 97.4 | 92.6 | 95.2 | 94.2 | 85.4 |
| Layer 3 | | 1.5 | 2.1 | 1.9 | 1.5 | 1 | 1.1 | 1.3 |
| Layer 4 | | 2.1 | 2.4 | 1.8 | 1.8 | 1.8 | 1.8 | |
| Layer 5 | | 2 | | 2.3 | 1.6 | 2.8 | 2.9 | |

TABLE II
density (g/cm3)

| | | | | | | | | after |
|---|---|---|---|---|---|---|---|---|
| | As | | | | | | | plasma |
| | grown | 1500° C. | 1600° C. | 1700° C. | 1800° C. | 1900° C. | 2000° C. | (reference) |
| Layer 1 | | | 0.9051 | 0.9957 | 0.9014 | 0.9842 | 0.9679 | 0.9858 |
| Layer 2 | 1.3685 | 0.9574 | 0.8584 | 0.8727 | 0.8174 | 0.7025 | 0.7483 | 0.7725 |
| Layer 3 | | 1.2025 | 2.5874 | 3.8433 | 2.7645 | 7.2556 | 6.1824 | 1.4498 |
| Layer 4 | | 1.7818 | 4.7788 | 6.9936 | 6.0848 | 9.6205 | 9.9925 | |
| Layer 5 | | 4.0056 | | 5.0864 | 5.256 | 4.8148 | 5.1352 | |

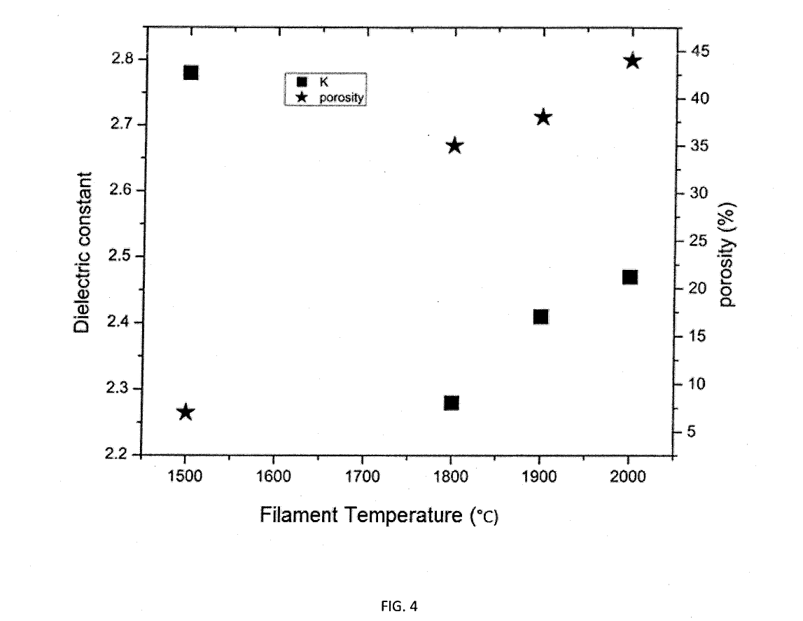

Using the sum of the thicknesses of all the layers as the total thickness of the film and C-V measurements, the dielectric constant of the films was determined and the results are shown in FIG. 4, together with the porosity of the different films, as determined by EP. The EP results show clearly that the open porosity increased with filament temperature: at 1500° C., the open porosity is still very low, while at 2000° C. it has approximately the same level as for the plasma treated low-k film. The dielectric value shows a steep decrease from the 1500° C. sample (2.78) to the 1800° C. sample (2.28), but k increased again for the higher filament treated samples. This paradox between porosity and dielectric constant is discussed below. From all these results, it is clear that depending on the film thickness the temperature and duration of the exposure treatment need to be adjusted accordingly. In this example, a longer exposure treatment with hydrogen (h) is required for low filament temperatures. Gathering, e.g., the results for the sample treated at 1500° C., one may conclude that a certain amount of porogen had been removed (from FTIR, XRR, EP, SIMS, C-V), but only from a relatively thin, upper part of the film (SIMS), while the lower part still remained full of porogen (SIMS), resulting in an overall higher density (XRR), lower porosity (EP) and higher k (C-V). However, the results at 1500° C. already indicated that the technique of removing porogen by hot wire dissociation of H₂ molecules as such, can be a viable technique to remove porogens from a SiCOH film.

While not wishing to be bound by any particular theory, it is believed from former experiments and from these analyses, there are strong indications that the higher concentration of atomic hydrogen, formed at the higher filament temperature, is the main cause for the more efficient removal of porogen in this system.

The explanation of the results of the different analyses for the temperatures between 1800° C. and 2000° C. is less trivial. Firstly, it is necessary to discuss in more detail the SIMS results. Firstly, one may clearly see that W is incorporated in the top of the SiCOH films. This incorporation may explain the high densities of the top layer in the XRR analyses: In general, the higher the filament temperature, the higher the density and the thicker the modified top layers. These different densities also have an effect on the sputter rate during the SIMS analysis: the higher the density, the slower the sputter rate, (when expressed in, e.g., nm/min). Also, the overall sputter yield depends on the composition of the film. For all these reasons, it is not trivial to obtain quantitative analysis results from a SIMS spectrum.

From the FTIR spectra, it is possible to conclude that the H treatment removed preferentially the C—CHₓ compounds and to a much lower degree the Si—CH₃ groups. Too much removal of the Si—CH₃ groups would lead to a more hydrophilic film, with inferior characteristics. Unfortunately, the FTIR spectra for the samples treated at 1900° C. and 2000° C. show an increase of the OH groups in the film. As the dielectric constant of water=80, this absorption has an impact of the final k value of the film. Hence, even with a higher porosity at 1900° C. and 2000° C. than at 1800° C., the final k value is higher for the higher temperatures. Other factors for this k-value increase is the higher density and higher W incorporation for the films treated at the highest temperatures.

In order to maximize further the porogen removal by this technique, it will be necessary to find a compromise between enough porogen removal in order to create a high porosity, and the incorporation of W and water into the low-k film.

The removal of porogens from a SiCOH film by hydrogen treatments in a HWCVD system has been studied. The temperature of the filaments plays an important role in the removal of the porogens: in general, the higher the temperature, the higher the removal and the higher the open porosity of the resulting films. Unfortunately, at the highest temperatures, there was also some water incorporation into the film and at the surface there was tungsten incorporation and some densification of the film. For these reasons, the lowest k-value was found at an intermediate filament temperature of 1800° C., resulting in a k-value of 2.28.

While the disclosure has been illustrated and described in detail in the drawings and foregoing description, such illustration and description are to be considered illustrative or exemplary and not restrictive. The disclosure is not limited to the disclosed embodiments. Variations to the disclosed embodiments can be understood and effected by those skilled in the art in practicing the claimed disclosure, from a study of the drawings, the disclosure and the appended claims.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein. It should be noted that the use of particular terminology when describing certain features or aspects of the disclosure should not be taken to imply that the terminology is being re-defined herein to be restricted to include any specific characteristics of the features or aspects of the disclosure with which that terminology is associated. Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘comprising’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide exemplary instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular embodiment of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

Where a range of values is provided, it is understood that the upper and lower limit, and each intervening value between the upper and lower limit of the range is encompassed within the embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. The indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific embodiments and examples described herein, but rather to also cover all modification and alternatives coming with the true scope and spirit of the invention.

What is claimed is:

1. A method for developing a film with a dielectric value below 2.3, comprising:
depositing a SiCOH film on a substrate, wherein the film comprises a matrix material forming a skeleton of the film co-deposited with a sacrificial porogen, wherein the sacrificial porogen is a cyclic hydrocarbon;
removing the sacrificial porogen from the film using a hot-wire-induced chemical vapor deposition process, whereby a porous film is obtained; and
UV curing the porous film, whereby a Young's modulus and hardness of the porous film are increased.

2. The method of claim 1, wherein removing the sacrificial porogen from the film using a hot-wire-induced chemical vapor process comprises:
positioning the substrate on which the film is on a substrate holder in a chamber of a hot-wire-induced chemical vapor deposition system;
supplying the chamber with a hydrogen-based gas;
heating a filament in the chamber to a predetermined temperature and for a predetermined time, whereby sacrificial porogen is removed from the film; thereafter
stopping a flow of the hydrogen-based gas;
cooling down the substrate and the system in an inert atmosphere, whereby the filament is preserved; and
removing the substrate from the tool.

3. The method of claim 2, wherein the filament is heated to a temperature of from 1500° C. to 2000° C.

4. The method of claim 2, wherein the filament is a single coiled type filament

5. The method of claim 4, wherein the filament comprises a refractory metal.

6. The method of claim 5, wherein the refractory metal is selected from the group consisting of W, Ta, Nb, and Mb.

7. The method of claim 2, wherein the filament is positioned at a predetermined distance from the film, such that a temperature of the substrate stays at a lower temperature than the filament, and such that a uniform distribution of hydrogen atoms on the film is obtained.

8. The method of claim 7, wherein the predetermined distance is about 5 cm.

9. The method of claim 7, wherein the temperature of the substrate is about 400° C.

10. The method of claim 1, further comprising ex situ monitoring a porosity and pore size distribution of the porous film using ellipsometric porosimetry.

11. The method of claim 1, further comprising ex situ monitoring by recording a Fourier transform infrared spectrum of the porous film in an absorption mode with a resolution better than 1 cm⁻¹, within a 400 to 4000 cm⁻¹ range, in a nitrogen atmosphere.

12. The method of claim 1, further comprising ex situ monitoring by recording an XRR spectra with an incident angle of 1500 sec for an omega-2 theta range of 200 sec to 10000 sec.

13. The method of claim 1, wherein the substrate is a wafer.

14. The method of claim 1, wherein the damage caused to the silica matrix is minimized during removal of the sacrificial porogen.
